(19) United States
(12) Patent Application Publication
(10) Pub. No.: US 2002/0182774 A1
(43) Pub. Date: Dec. 5, 2002

(54) Die-attach method and assemblies using film and epoxy bonds

(76) Inventor: James Kent Heckman, Chandler, AZ (US)

Correspondence Address: WEISS & MOY PC, 4204 NORTH BROWN AVENUE, SCOTTSDALE, AZ, 85251, US

(21) Appl. No.: 09/867,033

(22) Filed: May 29, 2001

(51) Int. Cl. H01L 23/52; H01L 29/40; H01L 23/48; H01L 21/44; H01L 21/48; H01L 21/50

(52) U.S. Cl. 438/118; 257/783

(57) ABSTRACT

A die-attach method and assembly using film and epoxy bonds speeds manufacturing for large die assemblies while providing improved bond characteristics. An adhesive film defining an epoxy flow mask is attached to the die or substrate, epoxy is dispensed within the epoxy flow mask area and the die is then bonded to the substrate. The film controls the flow of the epoxy, preventing spillover. Additionally, the epoxy area can be made small with respect to the die size, reducing the time required to dispense the epoxy and reducing the amount of epoxy material required.

### FIELD OF THE INVENTION

The present invention relates generally to semiconductor packaging, and more specifically, to a method and assembly for bonding semiconductor or other material to a substrate.

### BACKGROUND OF THE INVENTION

Semiconductors and other electronic and opto-electronic assemblies are fabricated in groups on a wafer. Known as “dies”, the individual devices are cut from the wafer and are then bonded to a carrier. Typically the carrier is an insulating or conductive substrate, but in some cases the substrate is a printed wiring board (PWB), lead-frame carrier, or other structure suitable for mechanically stabilizing the die. Other functions sometimes performed by the substrate are heat conduction for removing heat generated within the die due to power dissipation and electrical conduction, for providing a path for removing statically accumulated charge or providing a low resistance path to a power supply rail or other substrate bias.

Many techniques have been used to bond dies to a substrate, including epoxy bonding. In epoxy die-attach, epoxy is deposited on either the die or the substrate, and the die is then bonded to the substrate. The epoxy may be made highly conductive both electrically and thermally, generating a bond having characteristics superior to bonds generated using the adhesive film techniques described below. A disadvantage of the epoxy technique is that the epoxy is deposited using machines that dispense the epoxy on a surface by a mechanically positioned nozzle. For large dies, the process is slowed by the flow and positioning rates of the nozzle. Additionally, when the die and substrate are placed together, particularly for large dies, the epoxy flow is difficult to control and may result in non-uniformity and spillover.

An alternative bonding technique is liquid or dry film adhesion. In film adhesion processes, the film is applied to the side of the die that will be attached to the substrate, and then the film is adhered to the substrate. Liquid film may be screened or deposited on the die through a stencil mask. Dry film is typically mechanically cut and placed using mechanical placement machines. The advantage of the liquid film techniques is that large areas of film with a uniform thickness may rapidly applied in the manufacturing process. The disadvantage of the film techniques is that generally the films have low thermal and electrical conductivity.

Therefore, it would be desirable to provide a method and assembly having the advantages of film and epoxy die-attach, without the consequent disadvantages.

### SUMMARY OF THE INVENTION

A die-attach method and assembly using film and epoxy bonds speeds manufacturing for large die assemblies while providing improved bond characteristics. The apparatus comprises a substrate, a die (which may be a variety of devices including circuit modules, optoelectronic components and discretes) and an adhesive film defining an epoxy flow mask attached to the die or substrate. Epoxy is dispensed within the epoxy flow mask area and the die is then bonded to the substrate. The film controls the flow of the epoxy, providing control of the epoxy flow.

### BRIEF DESCRIPTION OF THE DRAWINGS

FIG. 1 is a pictorial diagram depicting a top view of a die-attach assembly prepared in accordance with an embodiment of the invention;

FIG. 2 is a pictorial diagram depicting a top view of a bonded die-attach assembly in accordance with an embodiment of the invention;

FIG. 3 is a pictorial diagram depicting a side view of the bonded assembly of FIG. 2; and

FIGS. 4A and 4B are depictions of a top view of die-attach assemblies prepared in accordance with an alternative embodiments of the invention.

The invention, as well as a preferred mode of use and advantages thereof, will best be understood by reference to the following detailed description of illustrative embodiments when read in conjunction with the accompanying drawings, wherein like as reference numerals indicate like parts throughout.

### DETAILED DESCRIPTION

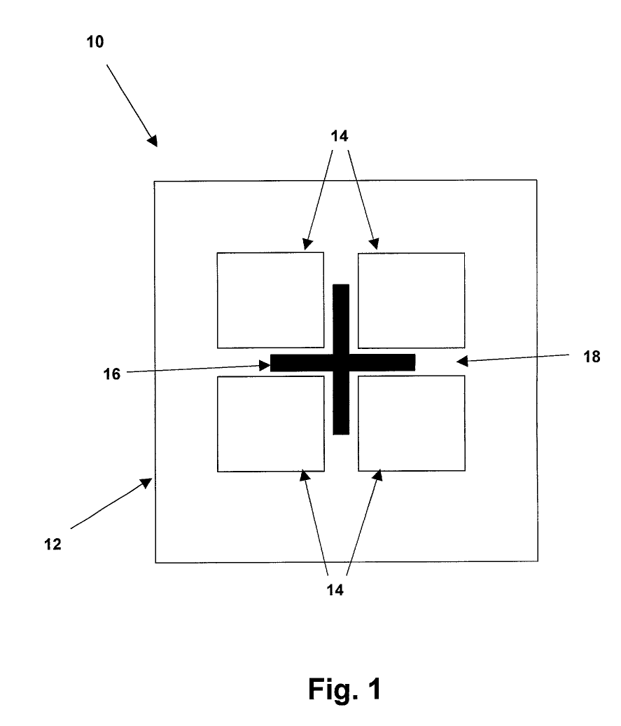

Referring now to the figures and in particular to FIG. 1, a top view of a die-attach assembly 10 prepared in accordance with an embodiment of the present invention is depicted. An adhesive film 14 is applied to a substrate 12 by a process appropriate to the film type. Epoxy 16 is also applied to substrate 12. Adhesive film 14 may be a dry transfer film cut and placed by a mechanical placement apparatus, or may be a liquid deposited film that is screened or stenciled on top of substrate 12. Adhesive film and epoxy bonding as used in the prior art are typically mutually exclusive bonding techniques.

While the depiction of the embodiment of the present invention in FIG. 1 shows an adhesive film composed of rectangular regions 14, the regions may be a single or multiple circular regions, ellipsoids, squares or other suitable shape.

In the embodiment of FIG. 1, adhesive film 14 defines an epoxy flow mask 18 for controlling the flow of epoxy as a die is applied to the prepared die-attach assembly 10. This differs from traditional adhesive film application in that the adhesive film applications as performed in the prior art typically cover the die-attach area and do not provide an epoxy flow mask, as none is needed. Liquid adhesive films are generally cured by ultra-violet (UV) radiation or heat, as appropriate to the adhesive material.

A “die” as used in the present invention includes a variety of assembly components and is not limited to integrated circuit wafer portions. A die may be an optosensor, memory module, discrete semiconductor, components for attachment to printed circuit boards, et cetera. Additionally, unsingulated dies may be prepared with adhesive by first preparing an entire wafer (on the back side) with adhesive film prior to wafer singulation. Following singulation, dies are then attached to the substrate.

Epoxy 16 is deposited within the epoxy flow mask 18 defined by adhesive film 14 and the epoxy flows to fill the space between adhesive film 14 segments. It is preferred that the epoxy flow mask 18 between adhesive film 14 segments extend to or past the die-attach area, so that epoxy 16 may flow without the formation of air bubbles or pressure that would be formed if the epoxy flow mask 18 had closed boundaries.

The use of epoxy 16 in combination with adhesive film 14 provides several advantages over past techniques and assemblies. The bond line formed by epoxy 16 is controlled by epoxy flow mask, permitting a control over the edges and the final thickness to a degree that was not previously possible. Epoxy also can be made highly conductive both thermally and electrically, permitting the bond of the present invention to both electrically and thermally couple the die to the substrate in a mechanically simple manner. Adhesive film is easier to control in a manufacturing process, especially when large dies are attached to a substrate.

In particular, the present invention facilitates the attaching of large dies that may be 40 mm in length per side or greater, to substrates. An amount of epoxy required to cover such a large area using conventional dispensing techniques requires a significant amount of time. Use of the adhesive film over most of the die-attach area reduces the amount of time required to manufacture the assembly, while retaining precision at the edges of the bond, as mentioned above. Additionally bond line thickness control is improved, as the adhesive film provides a spacer for the back of the die, thereby controlling the thickness of the epoxy bond to produce a bond of very consistent thickness. Control of the thickness, particularly maintaining consistent thickness throughout the bond area is very desirable, as die tilt is detrimental to the performance of the package assembly.

In the depiction of FIG. 1, the epoxy flow mask 18 defined by adhesive film 14 segments has a symmetrical cross shape. However, since the shape is defined by the adhesive film 14 segments as described above, the epoxy flow mask 18 may take on a variety of symmetrical or asymmetrical shapes as are appropriate for various dies. For example, as will be illustrated below, a circular epoxy flow mask may be defined by the shapes and placement of adhesive film segments. It would still be desirable that channels extend from the central circular epoxy flow mask to the sides of the die, in order to provide an exit path for gas and epoxy. Also, the depiction of FIG. 1 illustrates attaching to a continuous planar substrate 12, but the substrate may be a silicon substrate, a metal frame lead carriers, a printed wiring board (PWB), a ceramic substrate or other material know to those in the art of semiconductor packaging. The substrate may also assume various shapes. Use of the techniques of the present invention with PWBs may permit closing of the epoxy flow mask with holes drilled through the PWB to provide an epoxy exit path.

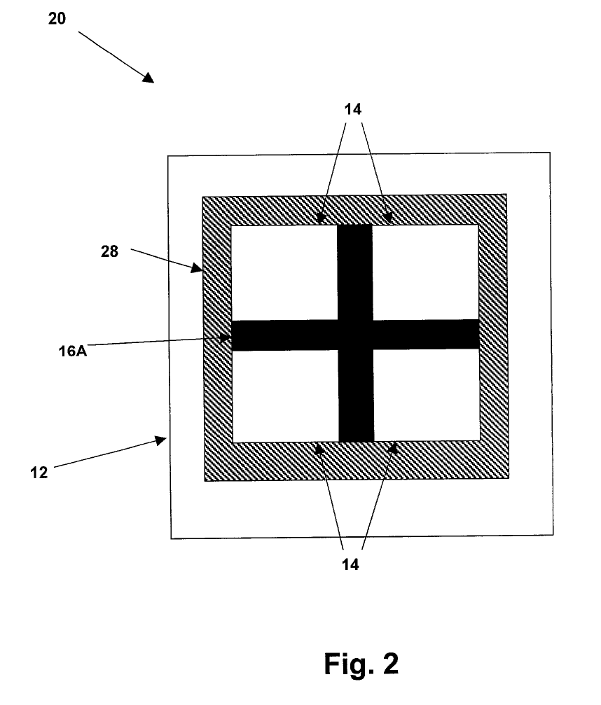

Referring now to FIG. 2, a top view of a bonded die-attach assembly 20 in accordance with an embodiment of the invention is depicted. A die 28 is shown placed over a substrate 12, with a central portion of die 28 removed for exemplary purposes, so that adhesive film 14 segments and epoxy 16A may be clearly viewed. Die 28 covers the region containing epoxy 16A and adhesive film segments 14 so that in actuality the view would be obscured by die 28.

After bonding, which generally will be a pressure bonding process between die 28 and substrate 12, epoxy 16A has flowed to fill the epoxy flow mask defined by adhesive film 14 segments. While the depiction of FIG. 2 shows the epoxy as ending at the edge of the film defining the epoxy flow mask region, in an actual assembly, some epoxy will extend past the edges of the film defining the epoxy flow mask region, and perhaps past the area of die 28.

While the illustrative embodiment of FIG. 1 and FIG. 2 shows the preparation of a die attach assembly 10 and subsequent bonded die-attach assembly 20 produced by bonding a die 28 to die-attach assembly 10, FIG. 2 also applies to a alternative embodiment of the invention, in which adhesive film 14 and epoxy 16 are applied to the bottom of die 28, and the die is then subsequently bonded to substrate 12. Variations of this method extend to application of epoxy 16 to the substrate 12 and adhesive film 14 to the die. Conversely, the epoxy may be applied to the die and adhesive film 14 to the substrate. In any arrangement of the elements of the present invention, as long as the epoxy material is initially deposited in a region in which the epoxy flow mask defined by the adhesive film 14 segments can control the flow of epoxy during bonding, the final assembly 20 should be similar and have the improved characteristics of the present invention.

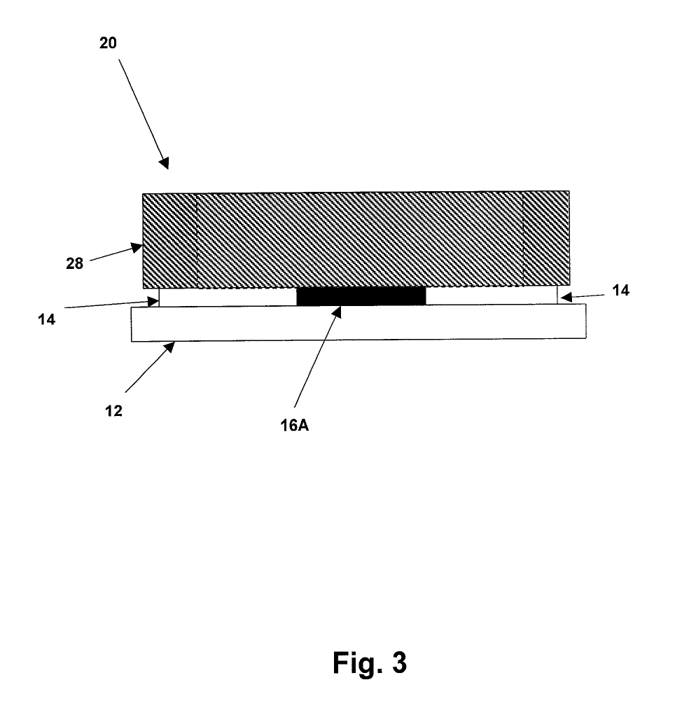

Referring now to FIG. 3, a side view of assembly 20 is depicted in accordance with an embodiment of the invention. Die 28 is attached to substrate 12 by both adhesive film 14 and epoxy 16A. Epoxy 16A has expanded to fill the epoxy flow mask region defined by adhesive film 14 segments. Due to the symmetrical cross pattern of the illustrative embodiment depicted in the figures, other side views of the assembly will be substantially similar.

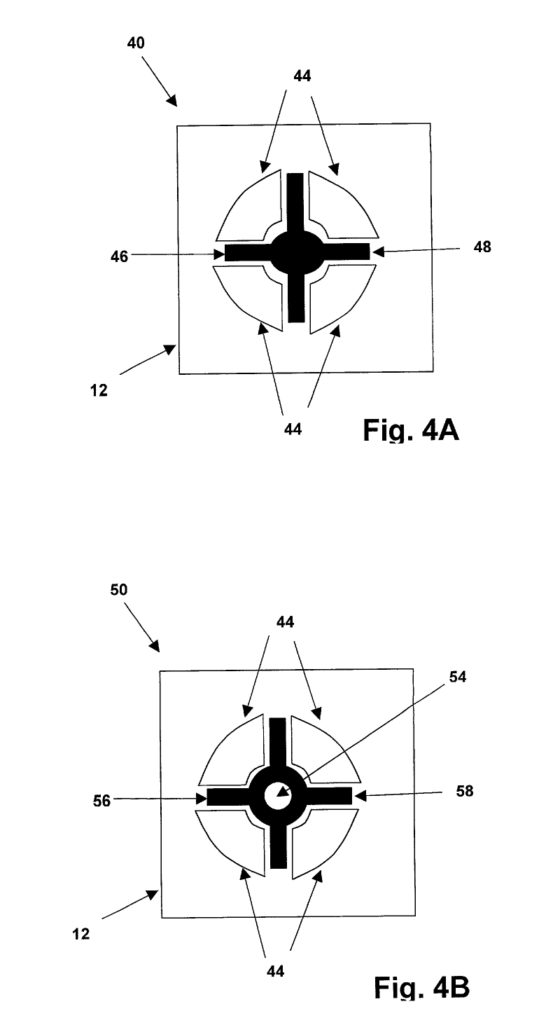

Referring now to FIG. 4A, a top view of a die-attach assembly 40 prepared in accordance with an alternative embodiment of the invention is depicted. An epoxy flow mask 48 having a central circular shape is defined by adhesive film 44 segments. The adhesive film 44 segments are annular segments and epoxy 46 is deposited in a symmetrical cross shape with a circular central region within epoxy flow mask 48 defined by adhesive film 44.

Referring now to FIG. 4B, a top view of another alternative embodiment of a die-attach assembly 50 is depicted. In addition to adhesive film 44 segments as depicted in FIG. 4A, an additional circular adhesive film segment 54 is applied, defining an epoxy flow mask 58 having a central void region. Additional adhesive film segment 54 reduces the amount of epoxy 56 required (as epoxy 56 is not deposited in the area defined by additional circular adhesive film segment 54) and assists in maintaining epoxy bond line thickness. The depiction of FIG. 4B illustrates an epoxy flow mask 58 having a central void and this may be extended to other shapes such as the rectangular shapes of the earlier-described illustrative embodiments. Use of voids within a large epoxy flow mask may aid in controlling the flow of epoxy 46 during the bonding process.

The above description of embodiments of the invention is intended to be illustrative and not limiting. Other embodiments of this invention will be obvious to those skilled in the art in view of the above disclosure and fall within the scope of the present invention.

What is claimed is:

1. A semiconductor assembly, comprising:
a die;
a substrate for attaching the die; and
a bonding layer comprising epoxy and adhesive film between the die and the substrate.

2. The semiconductor assembly of claim 1, wherein the adhesive film defines a reference surface whereby thickness of the epoxy as is determined by contact between the adhesive film and the die.

3. The semiconductor assembly of claim 1, wherein the adhesive film defines an epoxy flow mask for containing the epoxy.

4. The semiconductor assembly of claim 3, wherein the adhesive film comprises a plurality of discrete segments.

5. The semiconductor assembly of claim 4, wherein the adhesive film segments are rectangles and wherein the epoxy flow mask has a cross pattern defined by overlapping perpendicular rectangular regions.

6. The semiconductor assembly of claim 5, wherein the rectangular regions are of identical size and intersect at their centers, whereby the epoxy flow mask forms a symmetrical cross pattern defined by the intersecting rectangular regions.

7. The semiconductor assembly of claim 4, wherein the epoxy flow mask has a substantially circular central portion.

8. The semiconductor assembly of claim 7, wherein the adhesive film further includes a substantially circular central portion and the epoxy flow mask central portion defines an annulus around the central portion of the adhesive film.

9. The semiconductor assembly of claim 1, wherein the adhesive film is a dry transfer film.

10. The semiconductor assembly of claim 1, wherein the adhesive film is a screen printable liquid film cured to a solid form.

11. A semiconductor assembly, comprising:
a die;
a substrate for attaching the die; and
means for bonding the die to the substrate using epoxy and adhesive film.

12. The semiconductor assembly of claim 11, further comprising means for controlling the flow of the epoxy during attaching of the die to the substrate.

13. The semiconductor assembly of claim 12, wherein the flow controlling means controls the flow of the epoxy to form a symmetrical cross pattern.

14. The semiconductor assembly of claim 13, wherein the flow controlling means controls the flow of the epoxy to form a substantially circular pattern.

15. The semiconductor assembly of claim 11, further comprising means for controlling thickness of said epoxy using said adhesive film.

16. A method for attaching a die to a substrate, comprising:
applying an adhesive film to one of the die or the substrate;
depositing epoxy in an area on one of the die or the substrate; and
bonding the die to the substrate, whereby the adhesive film and the epoxy contribute to the bond characteristics of the resulting bond.

17. The method of claim 16, wherein the adhesive film defines an epoxy flow mask and wherein epoxy is deposited in an area within the epoxy flow mask.

18. The method of claim 16, wherein the adhesive film defines a reference surface for controlling the thickness of the epoxy.

19. The method of claim 16, wherein the adhesive film is a dry transfer film applied to the die or the substrate.

20. The method of claim 16, wherein the adhesive film is a liquid adhesive film and wherein the applying screen prints the liquid adhesive film on the die or the substrate.

21. The method of claim 16, wherein the adhesive film and the epoxy are applied to the substrate.

22. The method of claim 16, wherein the adhesive film and the epoxy are applied to the die.

23. The method of claim 16, wherein the adhesive film is applied to the die and the epoxy is applied to the substrate.

24. The method of claim 23, wherein the die is a portion of a wafer, wherein the method further comprises sawing the wafer to detach the die, and wherein the adhesive film is applied to wafer prior to sawing.

25. The method of claim 16, wherein the adhesive film is applied to the substrate and the epoxy is applied to the die.

26. A semiconductor product manufactured by the method of claim 16.
